(19) United States
(12) Patent Application Publication
(10) Pub. No.: US 2005/0088828 A1
(43) Pub. Date: Apr. 28, 2005

(54) Electronic apparatus with module-locking device

(75) Inventor: Jun Zhu, Su Zhou (CN)

Correspondence Address: QUINTERO LAW OFFICE, 1617 BROADWAY, 3RD FLOOR, SANTA MONICA, CA, 90404, US

(73) Assignee: BENQ CORPORATION, TAOYUAN (TW)

(21) Appl. No.: 10/951,833

(22) Filed: Sep. 28, 2004

(30) Foreign Application Priority Data
Oct. 27, 2003 (TW) TW92129735

(51) Int. Cl. H01R 4/50; H01R 13/625; H05K 5/00; H05K 5/04; H05K 5/06

(52) U.S. Cl. 361/732

(57) ABSTRACT

An electronic apparatus with a module-locking device. The electronic apparatus includes a housing, a module, a lock, and a driving device. The module is moveably disposed in the housing. The lock is disposed between a first position and a second position. When the lock is located in the first position, the lock is inserted in a through hole so that the module is fixed to the housing. When the lock is located in the second position, the lock separates from the through hole. The driving device is used to move the lock from the first position to the second position.

### BACKGROUND OF THE INVENTION

1. Field of the Invention

The invention relates to an electronic apparatus; in particular, the invention relates to an electronic apparatus with a module-locking device.

2. Description of the Related Art

An electronic apparatus is typically provided with a moveable module therein. For example, a printer is provided with a moveable printing module therein, and a scanner is provided with a moveable scanning module therein. The moveable module moves inside the electronic apparatus to perform a predetermined function. When the moveable module is not being used, it is often fixed in a predetermined position by a locking device.

The conventional locking device must be unlocked before the electronic apparatus can be used and be manually locked again before moving or transporting same. If the moveable module is not fixed by the locking device before transporting, damage thereto may occur.

In Taiwan Pub. No. 510629, an automatic locking device is provided. Referring to FIG. 1a and FIG. 1b, a first hook 2 is disposed on a housing 1 of an electronic apparatus, and a second hook 4 is disposed on a moveable module 3. Specifically, a magnetic member 5 is disposed on the first hook 2, and an electro-magnet 6 is disposed on the housing 1. When the electronic apparatus is turned on, the electro-magnet 6 generates magnetic force to attract the magnetic member 5. Thus, the first hook 2 is separated from the second hook 4 as shown in FIG. 1a so that the module 3 can move in the electronic apparatus. When the electronic apparatus is turned off, the electro-magnet 6 stops generating magnetic force, causing the magnetic member 5 to separate from the electro-magnet 6. Thus, the first hook 2 is engaged with the second hook 4 again as shown in FIG. 1b so that the module 3 can be fixed in an initial position.

The conventional locking device, however, can only lock the module in one direction but cannot completely lock the module. Specifically, when the first hook and the second hook are engaged in the electronic apparatus as shown in FIG. 1b, the module is only restrained in a leftward/rightward direction but not in a forward/backward direction. Thus, the module may move during transportation and be damaged.

In another conventional locking device, a laser is utilized. The structure of the locking device utilizing the laser, however, is complicated and expensive. Similarly, it can only lock the module in one direction.

### SUMMARY OF THE INVENTION

In order to address the disadvantages of the aforementioned locking device, the invention provides an electronic apparatus with an enhanced module-locking device capable of locking a moveable module.

Accordingly, the invention provides an electronic apparatus with a module-locking device. The electronic apparatus includes a housing, a module, a lock, and a driving device. The housing includes a through hole. The module is moveably disposed in the housing. The lock is disposed in the module in a manner such that it moves between a first position and a second position. When the lock is located in the first position, the lock is inserted into the through hole so that the module is fixed with the housing. When the lock is located in the second position, the lock is separated from the through hole. The driving device moves the lock from the first position to the second position so that the module can move relative to the housing.

In a preferred embodiment, the driving device is disposed in the module. The electronic apparatus further includes an elastic member connecting the lock and the module to maintain the lock in the first position. The elastic member may be a spring.

In another preferred embodiment, the electronic apparatus further includes a base and an elastic member. The base connects to the lock. The elastic member connects the module and the base to maintain the lock in the first position.

In another preferred embodiment, the driving device is disposed in the housing. The electronic apparatus further includes an elastic member connecting the lock and the module to maintain the lock in the first position. The driving device is an electro-magnet including a first magnetic pole, and the lock includes a second magnetic pole at a surface facing the electro-magnet. The first magnetic pole and the second magnetic pole are opposite.

In another preferred embodiment, the driving device is an electro-magnet, and the lock comprises metal.

It is understood that the electronic apparatus may be a scanner, and the module is a scanning module. Alternatively, the electronic apparatus may be a printer, and the module is a printing module.

In the invention, another electronic apparatus with a module-locking device is provided. The electronic apparatus includes a housing, a module, a lock, and a driving device. The module is moveably disposed in the housing and includes a through hole. The lock is disposed in the housing in a manner such that it moves between a first position and a second position. When the lock is located in the first position, the lock is inserted into the through hole so that the module is fixed to the housing. When the lock is located in the second position, the lock is separated from the through hole. The driving device moves the lock from the first position to the second position so that the module is moveable relative to the housing.

### BRIEF DESCRIPTION OF THE DRAWINGS

The present invention can be more fully understood by reading the subsequent detailed description and examples with references made to the accompanying drawings, wherein:

FIGS. 1a-1b are schematic views of a conventional locking device as disclosed in Taiwan Pub. No. 510629;

FIGS. 2a-2b are schematic views of an electronic apparatus as disclosed in a first embodiment of the invention;

FIGS. 3a-3b are schematic views of an electronic apparatus as disclosed in a second embodiment of the invention;

FIGS. 4a-4b are schematic views of an electronic apparatus as disclosed in a third embodiment of the invention;

FIGS. 5a-5b are schematic views of an electronic apparatus as disclosed in a fourth embodiment of the invention;

FIGS. 6a-6b are schematic views of an electronic apparatus as disclosed in a fifth embodiment of the invention;

FIGS. 7a-7b are schematic views of an electronic apparatus as disclosed in a sixth embodiment of the invention;

FIGS. 8a-8b are schematic views of an electronic apparatus as disclosed in a seventh embodiment of the invention; and

FIGS. 9a-9b are schematic views of an electronic apparatus as disclosed in an eighth embodiment of the invention.

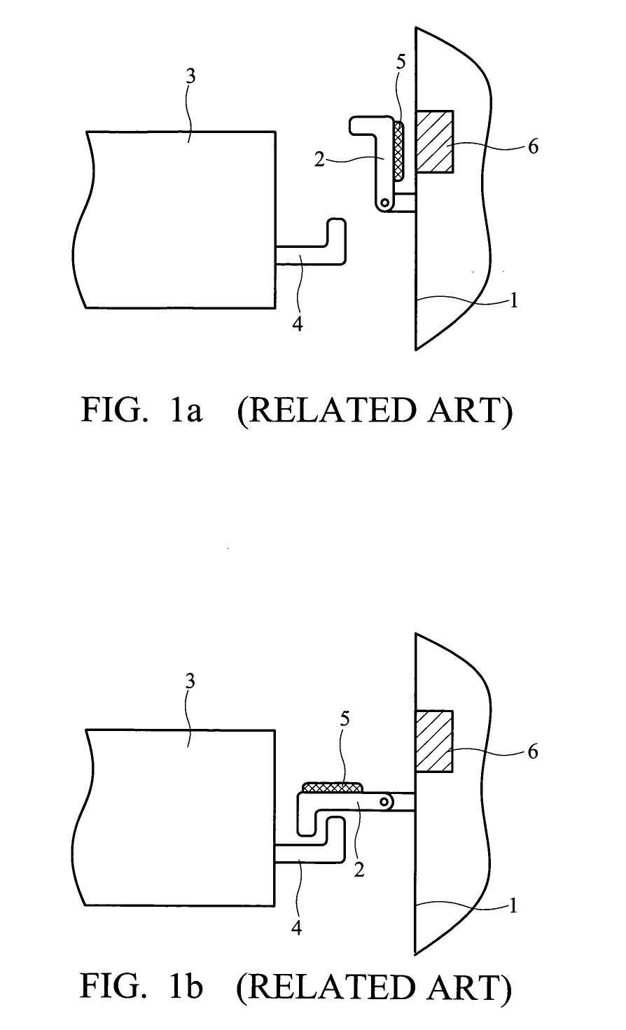

### DETAILED DESCRIPTION OF THE INVENTION

First Embodiment

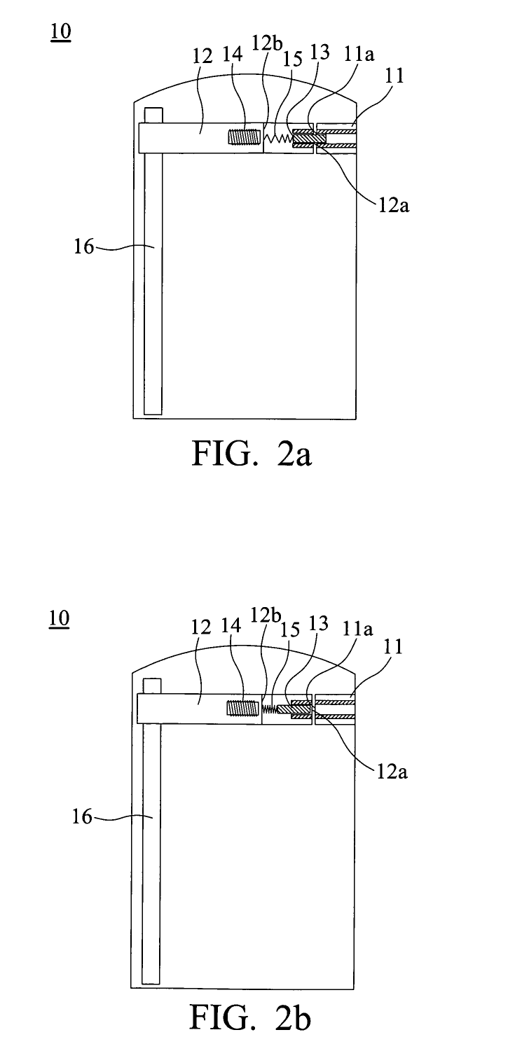

FIGS. 2a-2b are schematic views of an electronic apparatus 10 with a module-locking device as disclosed in a first embodiment of the invention. In this embodiment, the electronic apparatus 10 includes a housing 11, a module 12, a lock 13, a driving device 14, and an elastic member 15. The housing 11 includes a guide shaft 16 therein to guide the movement of the module 12. Additionally, the housing 11 is formed with a first through hole 11a at a predetermined position.

The module 12 is moveably disposed in the housing 11 via the guide shaft 16 and is formed with a second through hole 12a. The lock 13 is disposed in the module 12 in a manner such that it moves between an idle position (shown in FIG. 2a and hereinafter referred to as a first position) and a separated position (shown in FIG. 2b and hereinafter referred to as a second position). When the lock 13 is located in the first position, the lock 13 is inserted into the first through hole 11a via the second through hole 12a so that the module 12 is fixed to the housing 11. When the lock 13 is located in the second position, the lock 13 is separated from the first through hole 11a so that the module 12 can move relative to the housing 11.

The driving device 14 is disposed in the module 12 and electrically connected to a power source (not shown) in the electronic apparatus 10. The driving device 14 is used to drive the lock 13 from the first position to the second position. It is noted that the driving device 14 may be an electro-magnet and the lock 13 preferably comprises metal.

The elastic member 15 connects the lock 13 and a plate 12b of the module 12 to maintain the lock 13 in the first position. It is understood that the elastic member 15 may be a compression spring.

The structure of the electronic apparatus of this embodiment is described above, and its operation is described in the following.

When the electronic apparatus 10 is turned off, the elastic member 15 is in a normal state since the driving device 14 is not electrified. At this time, the lock 13 is inserted in the first through hole 11a of the housing 11 as shown in FIG. 2a so that the module 12 is fixed at a predetermined position in the housing 11. When the electronic apparatus 10 is turned on, the lock 13 is attracted by the magnetic force of the driving device 14 since the driving device 14 is electrified. Thus, the lock 13 separates from the first through hole 11a of the housing 11 as shown in FIG. 2b so that the module 12 can freely move relative to the housing 11.

It is understood that the electronic apparatus may be a scanner and the module is a scanning module. Alternatively, the electronic apparatus may be a printer, and the module is a printing module.

As stated above, the module can be stably locked at a predetermined position in the electronic apparatus. Specifically, since the lock is inserted in the through hole, the movement of the module can be completely limited in both leftward/rightward and upward/downward directions. Thus, damage to the module during transportation due to the vibration of the electronic apparatus can be prevented. Damage to other components, such as the glass, of the electronic apparatus can also be prevented.

Second Embodiment

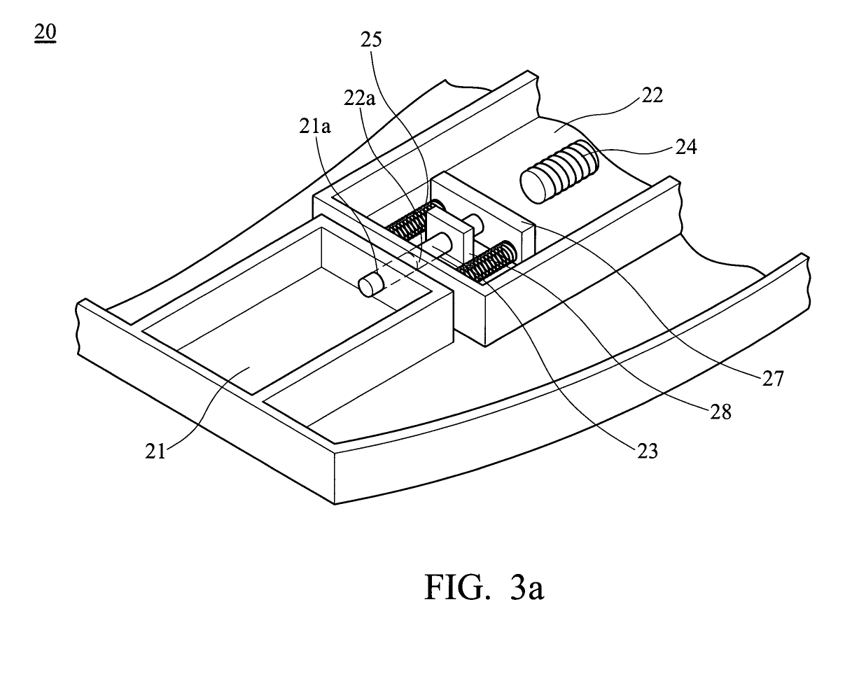

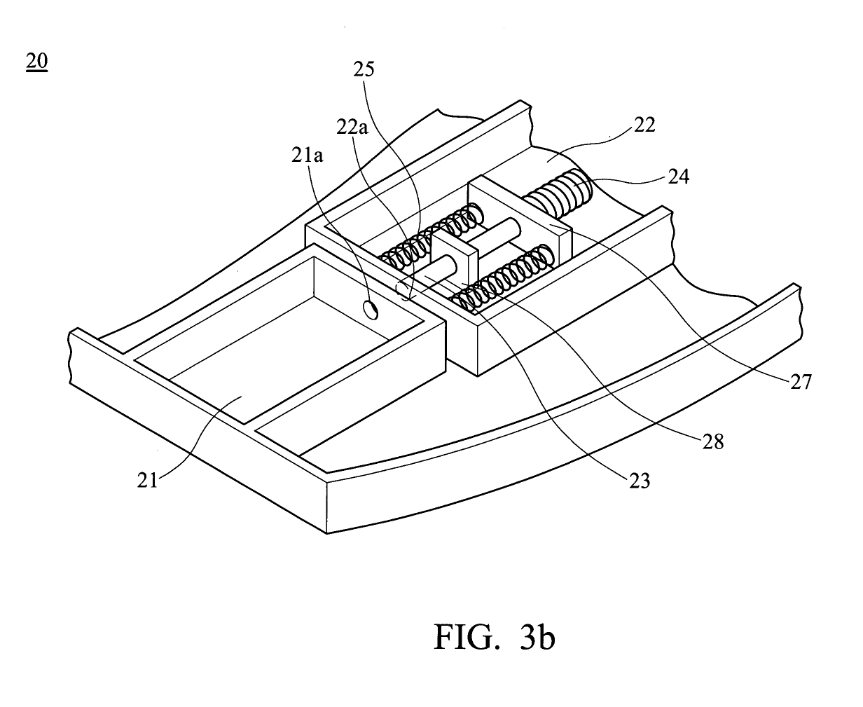

FIGS. 3a-3b are schematic views of an electronic apparatus 20 with a module-locking device as disclosed in a second embodiment of the invention. In this embodiment, the electronic apparatus 20 includes a housing 21, a module 22, a lock 23, a driving device 24, two elastic members 25, a base 27, and a guiding member 28. Since the housing 21, the module 22, the lock 23, and the driving device 24 of this embodiment are the same as those of the first embodiment, their description is omitted.

This embodiment differs from the first embodiment in that the electronic apparatus 20 includes a base 27 therein and the elastic member 25 is a tension member. Specifically, in this embodiment, the lock 23 connects to the base 27, and the elastic member 25 connects the module 22 and the base 27 as shown in FIG. 3a. Thus, when the driving device 24 is actuated, the elastic member 25 is in a tense state so that the lock 23 is separated from the housing 21 as shown in FIG. 3b.

The guiding member 28, which the lock 23 passes through, is disposed in the module 22 to guide the movement of the lock 23. Additionally, the lock 23 and the base 27 may be integrally formed.

Third Embodiment

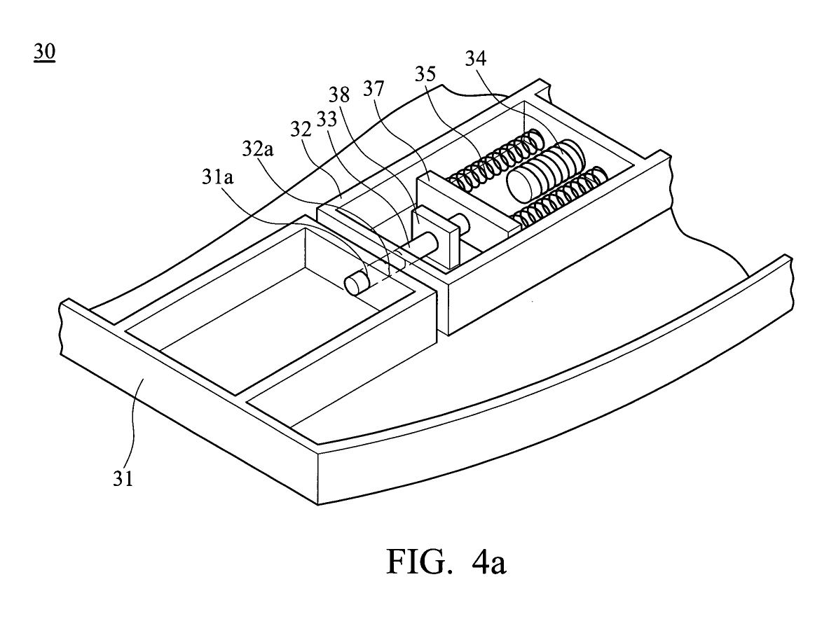

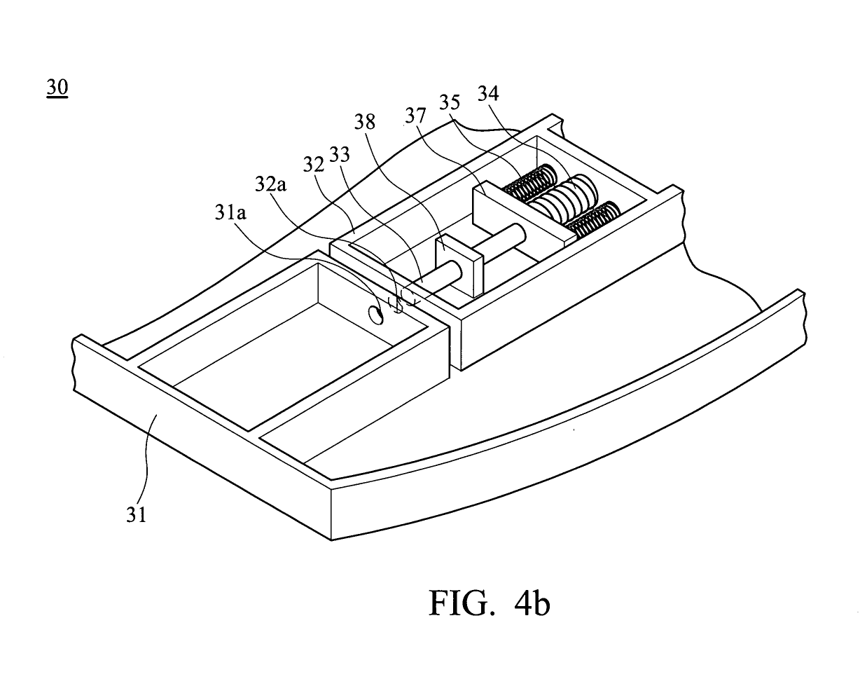

FIGS. 4a-4b are schematic views of an electronic apparatus 30 with a module-locking device as disclosed in a third embodiment of the invention. In this embodiment, the electronic apparatus 30 includes a housing 31, a module 32, a lock 33, a driving device 34, two elastic members 35, a base 37, and a guiding member 38. Since the housing 31, the module 32, the lock 33, the driving device 34, the base 37, and the guiding member 38 of this embodiment are the same as those of the second embodiment, their description is omitted.

This embodiment differs from the second embodiment in that each elastic member 35 is a compression member. Specifically, in this embodiment, each elastic member 35 connects the base 37 and another wall of the module 32 as shown in FIG. 4a. Thus, when the driving device 34 is actuated, the elastic member 35 is in a compressed state so that the lock 33 is separated from the housing 31 as shown in FIG. 4b.

Fourth Embodiment

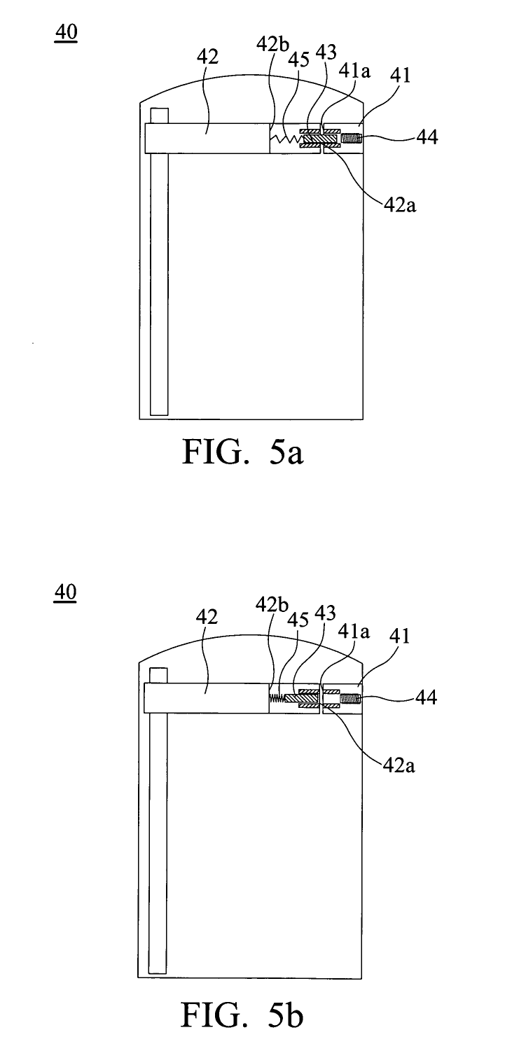

FIGS. 5a-5b are schematic views of an electronic apparatus 40 with a module-locking device as disclosed in a fourth embodiment of the invention. In this embodiment, the electronic apparatus 40 includes a housing 41, a module 42, a lock 43, a driving device 44, and an elastic member 45. Since the housing 41, the module 42, and the elastic member 45 of this embodiment are the same as those of the first embodiment, their description is omitted.

This embodiment differs from the first embodiment in that the driving device 44 is disposed in the housing 41. The lock 43 is made of magnetized metal, or includes a magnetic pole at a surface facing the driving device 44. Specifically, the driving device 44 is an electro-magnet including a first magnetic pole, and the lock 43 includes a second magnetic pole. The first magnetic pole and the second magnetic pole are opposite. Thus, when the driving device 44 is actuated, the lock 43 can return into the module 42 so that the lock 43 is separated from the housing 41 as shown in FIG. 5b.

Fifth Embodiment

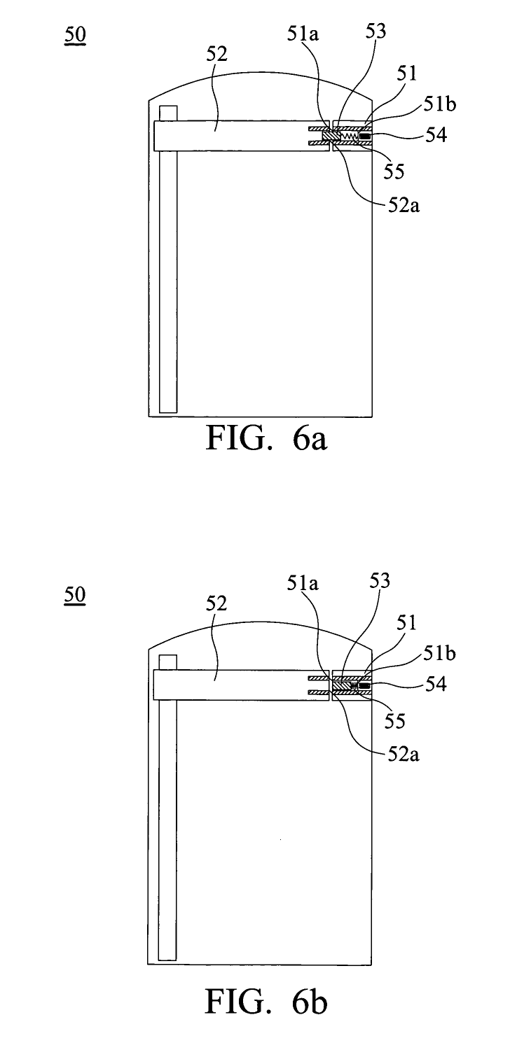

FIGS. 6a-6b are schematic views of an electronic apparatus 50 with a module-locking device as disclosed in a fifth embodiment of the invention. In this embodiment, the electronic apparatus 50 includes a housing 51, a module 52, a lock 53, a driving device 54, and an elastic member 55. Since the housing 51 and the module 52 of this embodiment are the same as those of the first embodiment, their description is omitted.

This embodiment differs from the first embodiment in that the lock 53, the driving device 54, and the elastic member 55 are disposed in the housing 51. Additionally, when the lock 53 is in an idle state, it is inserted in the second through hole 52a of the module 52 via the first through hole 51a of the housing 51. When the driving device 54 is actuated, the lock 53 can return into the housing 51 so that the lock 53 is separated from the module 52 as shown in FIG. 6b.

Sixth Embodiment

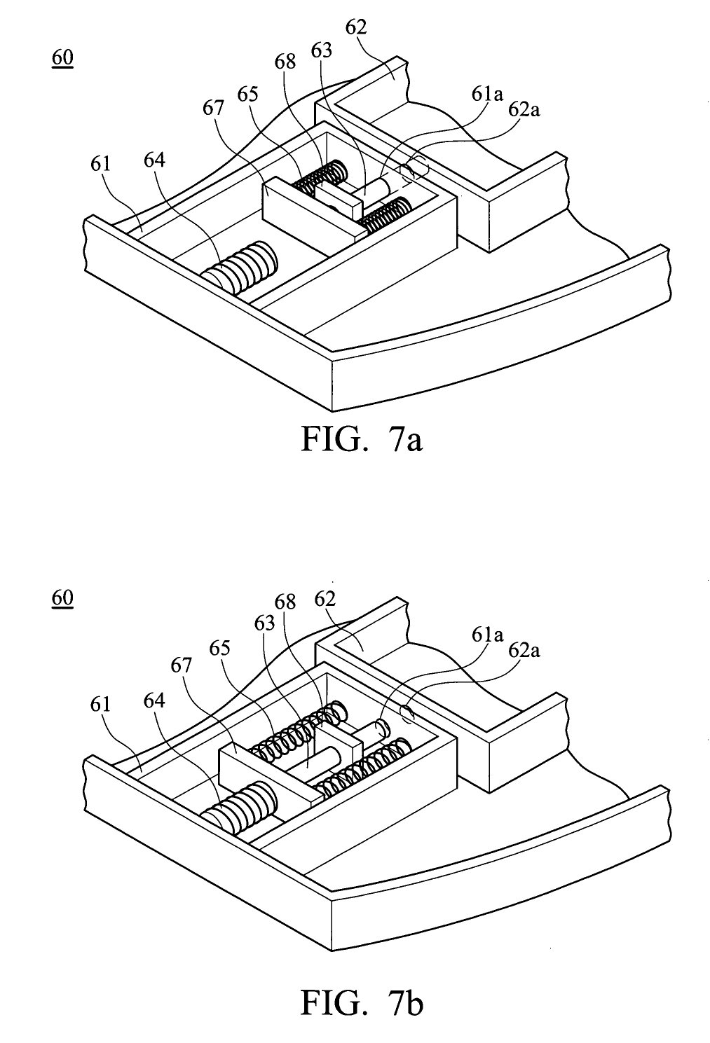

FIGS. 7a-7b are schematic views of an electronic apparatus 60 with a module-locking device as disclosed in a sixth embodiment of the invention. In this embodiment, the electronic apparatus 60 includes a housing 61, a module 62, a lock 63, a driving device 64, two elastic members 65, a base 67, and a guiding member 68. Since the housing 61 and the module 62 of this embodiment are the same as those of the second embodiment, their description is omitted.

This embodiment differs from the second embodiment in that the lock 63, the driving device 64, the elastic members 65, the base 67, and the guiding member 68 are disposed in the housing 61. Additionally, when the lock 63 is in an idle state, it is inserted in the second through hole 62a of the module 62 via the first through hole 61a of the housing 61. When the driving device 64 is actuated, the lock 63 can return into the housing 61 so that the lock 63 is separated from the module 62 as shown in FIG. 7b.

Seventh Embodiment

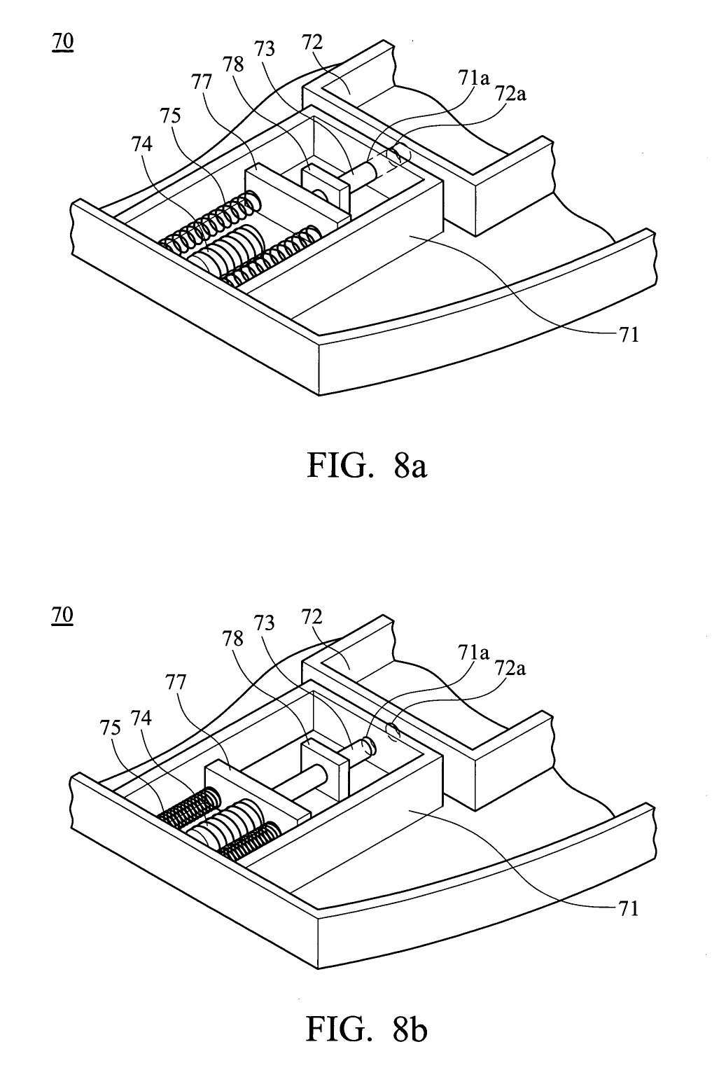

FIGS. 8a-8b are schematic views of an electronic apparatus 70 with a module-locking device as disclosed in a seventh embodiment of the invention. In this embodiment, the electronic apparatus 70 includes a housing 71, a module 72, a lock 73, a driving device 74, two elastic members 75, a base 77, and a guiding member 78. Since the housing 71 and the module 72 of this embodiment are the same as those of the third embodiment, their description is omitted.

This embodiment differs from the third embodiment in that the lock 73, the driving device 74, the elastic members 75, the base 77, and the guiding member 78 are disposed in the housing 71. Additionally, when the lock 73 is in an idle state, it is inserted in the second through hole 72a of the module 72 via the first through hole 71a of the housing 71. When the driving device 74 is actuated, the lock 73 can return into the housing 71 so that the lock 73 is separated from the module 72 as shown in FIG. 8b.

Eighth Embodiment

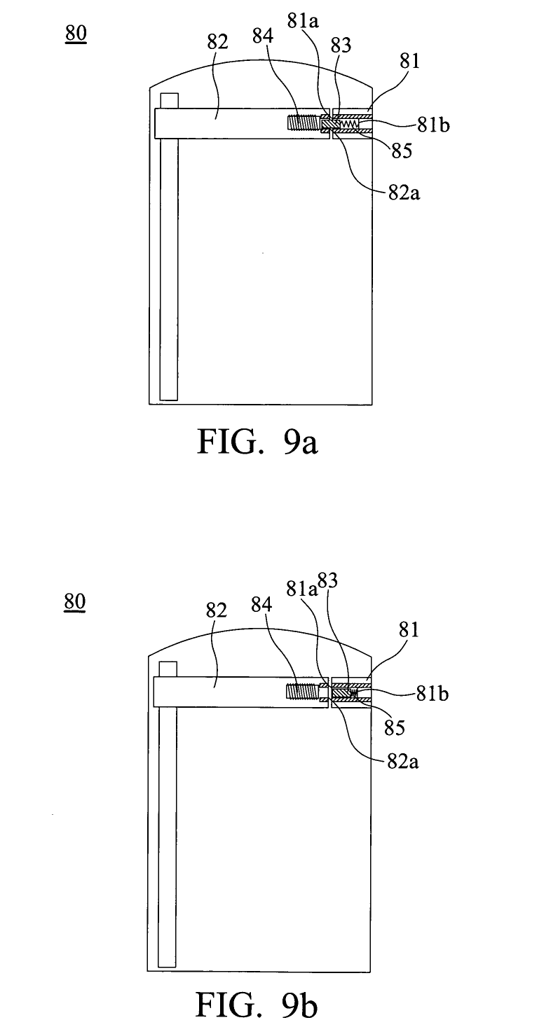

FIGS. 9a-9b are schematic views of an electronic apparatus 80 with a module-locking device as disclosed in an eighth embodiment of the invention. In this embodiment, the electronic apparatus 80 includes a housing 81, a module 82, a lock 83, a driving device 84, and an elastic member 85. Since the housing 81, the module 82, and the elastic member 85 of this embodiment are the same as those of the fifth embodiment, their description is omitted.

This embodiment differs from the fifth embodiment in that the driving device 84 is disposed in the module 82. The lock 83 is made of metal with magnetism, or includes a magnetic pole at a surface facing the driving device 84. Specifically, the driving device 84 is an electro-magnet including a first magnetic pole, and the lock 83 includes a second magnetic pole. The first magnetic pole and the second magnetic pole are opposite. Thus, when the driving device 84 is actuated, the lock 83 can return into the housing 81 so that the lock 83 is separated from the module 82 as shown in FIG. 9b.

While the invention has been described by way of example and in terms of the preferred embodiment, it is to be understood that the invention is not limited to the disclosed embodiment. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. An electronic apparatus with a module-locking device comprising:
a housing including a through hole;
a module moveably disposed in the housing;
a lock disposed in the module in a manner such that the lock moves between a first position and a second position, wherein the lock is inserted in the through hole so that the module is fixed to the housing when the lock is located in the first position, and the lock separates from the through hole when the lock is located in the second position; and
a driving device for moving the lock from the first position to the second position so that the module is moveable relative to the housing.

2. The electronic apparatus as claimed in claim 1, wherein the driving device is disposed in the module.

3. The electronic apparatus as claimed in claim 2, further comprising an elastic member connecting the lock and the module to maintain the lock in the first position.

4. The electronic apparatus as claimed in claim 3, wherein the elastic member is a spring.

5. The electronic apparatus as claimed in claim 2, further comprising:
a base connecting to the lock; and
an elastic member connecting the module and the base to maintain the lock in the first position.

6. The electronic apparatus as claimed in claim 1, wherein the driving device is disposed in the housing.

7. The electronic apparatus as claimed in claim 6, further comprising an elastic member connecting the lock and the module to maintain the lock in the first position.

8. The electronic apparatus as claimed in claim 7, wherein the driving device is an electro-magnet including a first magnetic pole, the lock includes a second magnetic pole at a surface facing the electro-magnet, and the first magnetic pole and the second magnetic pole are opposite.

9. The electronic apparatus as claimed in claim 1, wherein the driving device is an electro-magnet.

10. The electronic apparatus as claimed in claim 9, wherein the lock comprises metal.

11. The electronic apparatus as claimed in claim 1, wherein the electronic apparatus is a scanner, and the module is a scanning module.

12. The electronic apparatus as claimed in claim 1, wherein the electronic apparatus is a printer, and the module is a printing module.

13. An electronic apparatus with a module-locking device comprising:
a housing;
a module, moveably disposed in the housing, including a through hole;
a lock disposed in the housing in a manner such that the lock moves between a first position and a second position, wherein the lock is inserted in the through hole so that the module is fixed to the housing when the lock is located in the first position, and the lock separates from the through hole when the lock is located in the second position; and
a driving device for moving the lock from the first position to the second position so that the module is moveable relative to the housing.

14. The electronic apparatus as claimed in claim 13, wherein the driving device is disposed in the housing.

15. The electronic apparatus as claimed in claim 14, further comprising an elastic member connecting the lock and the housing to maintain the lock in the first position.

16. The electronic apparatus as claimed in claim 15, wherein the elastic member is a spring.

17. The electronic apparatus as claimed in claim 14, further comprising:
a base connecting to the lock; and
an elastic member connecting the housing and the base to maintain the lock in the first position.

18. The electronic apparatus as claimed in claim 13, wherein the driving device is disposed in the module.

19. The electronic apparatus as claimed in claim 18, further comprising an elastic member connecting the lock and the housing to maintain the lock in the first position.

20. The electronic apparatus as claimed in claim 19, wherein the driving device is an electro-magnet including a first magnetic pole, the lock includes a second magnetic pole at a surface facing the electro-magnet, and the first magnetic pole and the second magnetic pole are opposite.

21. The electronic apparatus as claimed in claim 13, wherein the driving device is an electro-magnet.

22. The electronic apparatus as claimed in claim 21, wherein the lock comprises metal.

23. The electronic apparatus as claimed in claim 13, wherein the electronic apparatus is a scanner, and the module is a scanning module.

24. The electronic apparatus as claimed in claim 13, wherein the electronic apparatus is a printer, and the module is a printing module.
